(19) United States
(12) Patent Application Publication
(10) Pub. No.: US 2015/0311910 A1
(43) Pub. Date: Oct. 29, 2015

(54) CURRENT COMPARATOR OFFSET CALIBRATION IN DIGITAL-TO-ANALOG CONVERTER CALIBRATIONS

(71) Applicant: QUALCOMM Incorported, San Diego, CA (US)

(72) Inventors: Tongyu SONG, San Diego, CA (US); Derui KONG, San Diego, CA (US)

(21) Appl. No.: 14/601,180

(22) Filed: Jan. 20, 2015

Related U.S. Application Data
(60) Provisional application No. 61/983,952, filed on Apr. 24, 2014.

(51) Int. Cl. H03M 1/10; H03M 1/66

(52) U.S. Cl. CPC H03M 1/1028; H03M 1/66

(57) ABSTRACT

In an aspect of the disclosure, a method and an apparatus are provided for calibrating a current comparator circuit associated with a DAC element. The apparatus receives an output of a current comparator module, determines calibration data using a finite state machine (FSM) based on the output of the current comparator module, and reduces an offset current at an input of the current comparator module based on the calibration data from the FSM.

### CROSS-REFERENCE TO RELATED APPLICATIONS

This application claims the benefit of U.S. Provisional Application Ser. No. 61/983,952 entitled “CURRENT COMPARATOR OFFSET CALIBRATION IN DIGITAL-TO-ANALOG CONVERTER CALIBRATIONS” and filed on Apr. 24, 2014, which is expressly incorporated by reference herein in its entirety.

### BACKGROUND

1. Field

Various embodiments disclosed herein relate generally to methods and systems for digital-to-analog conversion. More specifically, this disclosure relates to methods and systems for calibrating a digital-to-analog converter (DAC).

2. Background

DACs are utilized in a wide variety of applications. DACs can be susceptible to various types of errors including but not limited to errors related to current or voltage source mismatches, gain and offset errors, as well as errors caused by external signal paths. To achieve improved performance in the areas of signal-to-noise and distortion ratio (SNDR), total harmonic distortion (THD), and spurious free dynamic range (SFDR), self-calibration techniques are utilized to calibrate the output provided by a DAC.

One self-calibration technique employs controllable current sources and a calibration circuit to tune current source values. The calibration circuit compares the current source value provided by a selected controllable current source to a reference current value and adjusts the controllable current source in accordance with the comparison. However, with such conventional self-calibration of current source values, DACs can be susceptible to large integral non-linearity (INL) errors across the bit elements of the DAC, which can result in large DAC performance variations. The large or unbounded INL errors can be due to calibration errors or variations. The calibration errors can be caused by finite calibration resolution, current comparator noise, and other issues.

According to another self-calibration technique, an analog-to-digital converter digitizes most significant bit (MSB) codes at the output of the DAC and compares the MSB codes to expected outputs to obtain errors which are stored for each code. The errors are used to drive the DAC and compensate for the errors. However, this ADC-based self-calibration technique requires an ADC with adequate resolution which significantly adds to the silicon area and power consumption of the DAC.

### SUMMARY

In an aspect of the disclosure, a method and an apparatus are provided for calibrating a DAC element. The apparatus receives an output of a current comparator module, determines calibration data using a finite state machine (FSM) based on the output of the current comparator module, and reduces an offset current at an input of the current comparator module based on the calibration data from the FSM.

In an aspect of the disclosure, an apparatus for calibrating a DAC element includes a current comparator module coupled to the DAC element. The current comparator module is configured to calibrate a current source corresponding to the DAC element. The apparatus further includes a calibration module coupled to the current comparator module and configured to reduce an offset current of the current comparator module. The calibration module includes an FSM configured to receive feedback from the current comparator module and to generate calibration data based on the feedback, and a comparator DAC configured to reduce an offset current of the current comparator module based on the calibration data from the FSM.

### BRIEF DESCRIPTION OF THE DRAWINGS

FIG. 1 is a diagram illustrating a DAC calibration circuit in accordance with various aspects of the disclosure.

FIG. 2 is a diagram illustrating a DAC calibration circuit in accordance with various aspects of the disclosure.

FIG. 3 is a diagram illustrating a DAC calibration circuit in accordance with various aspects of the disclosure.

FIG. 4 is a diagram illustrating a timing sequence for an FSM in accordance with various aspects of the disclosure.

FIG. 5 is a flow chart of a method of calibrating a current comparator circuit associated with a DAC element in accordance with various aspects of the disclosure.

FIG. 6 is a block diagram of a DAC in accordance with various aspects of the disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Certain aspects are directed to calibration error reduction methods and circuits. In one aspect, such a method is applied in a DAC (e.g., a controlled current source DAC) that inlcudes a current comparator configured to calibrate a current source associated with a DAC element. According to one embodiment, an offset current of the current comparator is reduced by employing an n-bit (e.g., 6 bit) DAC and a digital finite state machine (FSM). The reduction of the offset current may increase calibration accuracy by improving the accuracy of the residual current error sampling for INL corrections and may achieve such reduction of the offset current without employing a large current comparator. For example, the techniques disclosed herein may be implemented in 20 nm TxDAC.

To achieve good performance in a DAC, such as high SNDR, THD, and SFDR, accurate current source matching for each DAC element is need. In previous DAC designs, accurate current source matching was achieved by using large transistor-based current sources. However, due to the limitation of the device sizes offered by available CMOS process technologies, acceptable current matching performance may not be achieved. To improve the accuracy of the current source matching, a self-calibration technique may be used to tune the different current source values of each DAC element to a desired level. Despite any additional circuitry that may be required for the calibration, due to the significant reduction of current source area, the total die area may decrease.

To improve DAC calibration accuracy, integral nonlinearity (INL) correction may be applied. In one approach, for example, the residual current error determined from a previous calibration of a DAC element (also referred to as DAC bit element) may be used to calibrate a successive DAC element.

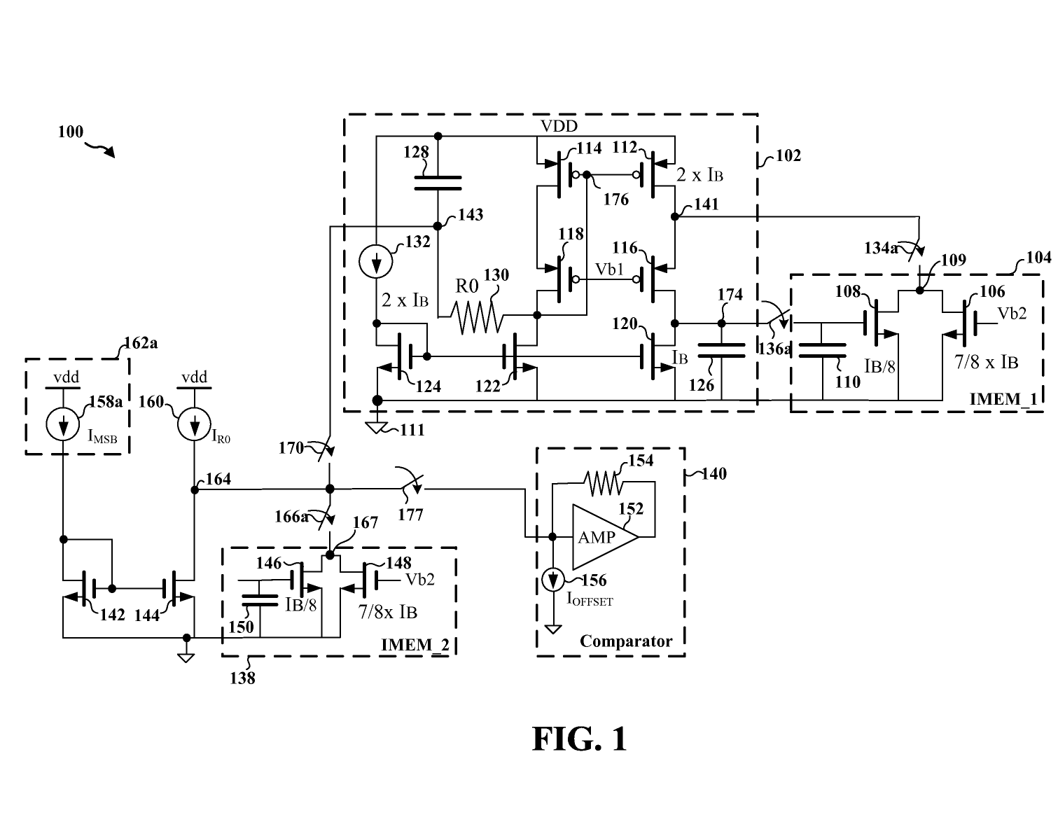

FIG. 1 is a diagram illustrating a DAC calibration circuit 100 in accordance with various aspects of the disclosure. As shown in FIG. 1, DAC calibration circuit 100 includes memory cell (IMEM_1) 104, memory cell (IMEM_2) 138, charging circuit 102, and a current comparator circuit 140. In an aspect, charging circuit 102 includes transistors 112, 114, 116, 118, 120, 122, 124, capacitors 126 and 128, resistor (R0) 130, and current source 132.

In an aspect, memory cell 104 includes transistors 106 and 108 and capacitor 110. In one embodiment, transistors 106 and 108 may be configured to split the current between them such that the current is divided into ⅛^{th} and ⅞^{th} of the total current at node 109. The gate of transistor 106 is controlled by a bias Vb2 to enable the transistor 106 to conduct approximately ⅞^{th} the total current at node 109 in one embodiment. One terminal of capacitor 110 is connected to ground 111 and the other terminal of the capacitor 110 is connected to the gate of the transistor 108. A first terminal of transistor 108 is connected to the first terminal of the transistor 106 at node 109. The second terminals of both transistors 108 and 106 are connected to ground 111. In an aspect, memory cell 138 including transistors 146, 148 and capacitor 150 may be configured to operate in a manner similar to memory cell 104 as discussed infra.

In an aspect, switch 134a is closed to connect node 109 of memory cell 104 to node 141 of the charging circuit 102 to store a residual current error associated with current sources 158a and 160 in memory cell 104. For example, current source 158a may be a current source of a DAC element 162a that is calibrated with respect to a reference current source (e.g., current source 160). In an aspect, current source 158a may be calibrated for a DAC element and may provide current I_{MSBC} (e.g., I_{MSBC}=I_{MSB}+I_{CAL}) and current source 160 may provide a reference current I_{REF} (e.g., I_{REF}=I_{R0}+I_{REFDAC}).

In one aspect, succeeding DAC elements (also referred to as DAC bit elements) may each be coupled to transistor 142 to effect residual current error sampling and storing operations. In an aspect, each DAC bit element (e.g., DAC bit element 162a) may have its own current source (e.g., current source 158a). In such aspect, transistors 142, 144, source 160, and charging circuit 102 may be shared for all DAC bit elements (e.g., DAC bit elements 162a, 162b), such that each succeeding DAC bit element may be selectively coupled (e.g., via switches) to transistor 142 one at a time so that calibration may be performed. For example, a first DAC bit element may be coupled to the transistor 142 and calibration of the first DAC bit element may be performed. After calibration of the first DAC bit element is completed, the residual error of the calibration (e.g., the residual current error) is stored in IMEM_1 104 or IMEM_2 138. Thereafter, the first DAC bit element may be decoupled from the transistor 142 and a second DAC bit element (e.g., a succeeding DAC bit element) may be coupled to the transistor 142 in order to calibrate the second DAC bit element.

With reference to FIG. 1, before calibration of current source 158a of DAC bit element 162a, memory cell 104 may be used to store a dc current. The dc current may be a known fixed value or may be sampled.

In an aspect, charging circuit 102 may include nodes 141 and 143. In such aspect, in order to sample and store the residual current error between current sources 158a and 160 at node 164, switch 166a may connect node 164 to node 167, switch 170 may connect node 143 to node 164, switch 134a may connect node 109 to node 141, and switch 136a may connect node 174 to the gate of transistor 108. With such a configuration, the residual current error (e.g., Δ₁) existing after calibration of current source 158a is provided from node 143 to node 176. The provision of the residual current error from node 143 charges capacitor 126 to a level that is approximately the sum of the current comparator circuit offset current (e.g., I_{OFFSET} 156) and the residual current error (e.g., Δ₁). Capacitor 110 is charged via closed switch 136a to a similar level, thereby storing the sum of the current I_{OFFSET} and the residual current error (e.g., Δ₁).

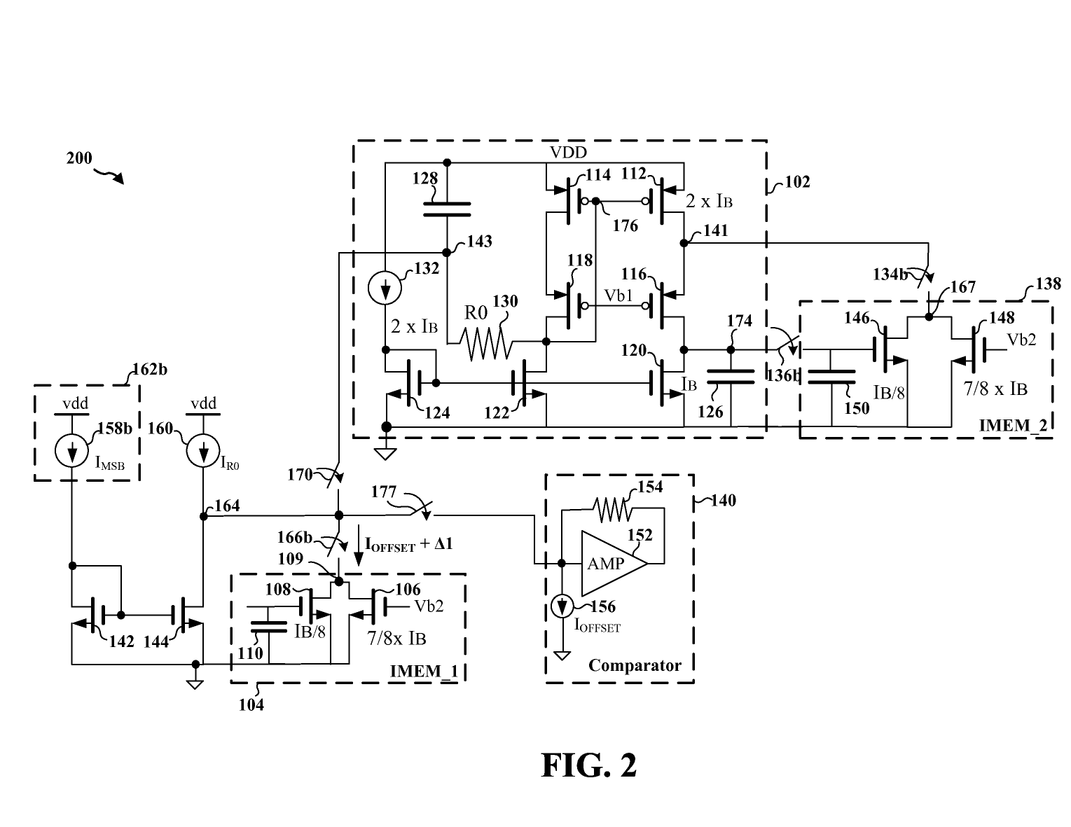

FIG. 2 is a diagram illustrating a DAC calibration circuit 200 in accordance with various aspects of the disclosure. In an aspect, with reference to FIG. 2, when calibrating the current source 158b of a successive DAC bit element 162b, memory cell 104 (IMEM_1) may be coupled to the node 164. As previously discussed, memory cell 104 may be storing the sum of the current I_{OFFSET} and the residual current error (e.g., Δ₁) from the calibration of a preceding DAC bit element 162a. Accordingly, in such aspect, switch 166b may couple node 109 to node 164, switch 170 may electrically disconnect node 164 from node 143, and switch 177 may couple node 164 to the input of the current comparator circuit 140. In such a configuration, capacitor 110 drives transistor 108 such that the memory cell 104 sinks an amount of current equal to the sum of the current I_{OFFSET} and the residual current error (Δ₁) during calibration of the current source 158b of the DAC bit element 162b to improve accuracy of the calibration.

In an aspect, the current comparator circuit 140 may include one or more amplifiers, such as amplifier 152, which may be implemented using a feedback configuration (e.g., via resistor 154). In an aspect, the one or more amplifiers of the current comparator circuit 140 may be configured in one or more amplifier stages. In an aspect, the amplifier 152 may represent a first amplifier stage of the current comparator circuit 140. For example, the amplifier 152 may be a transimpedance amplifier (TIA). It should be understood that the current comparator circuit 140 may include additional circuitry (not shown for ease of illustration) for effectively performing a current comparator function.

For example, the current comparator circuit 140 may be configured to convert a relatively small input current into an amount of voltage, and may amplify the amount of voltage for comparison. The offset current I_{OFFSET} 156 of the current comparator circuit 140 may affect the INL corrections (e.g., the sampling and storing of the residual current errors).

For example, with the offset current I_{OFFSET} 156 of the current comparator circuit 140, an initial INL calibration result may be represented as I₁=I₀+I_{OFFSET}+Δ₁ and a subsequent INL calibration result may be represented as I₂+I_{OFFSET}+Δ₁=I₀+I_{OFFSET}+Δ₂. Therefore, simplifying further, I₂=I₀+Δ₂−Δ₁. Accordingly, the calibration results for a 64^{th} DAC bit element may be represented as I₆₃+I_{OFFSET}+Δ₆₂=I₀+I_{OFFSET}+Δ₆₃. Therefore, simplifying further, I₆₃=I₀+Δ₆₃−Δ₆₂. Therefore, it should be noted that the value sampled by an INL correction circuit (e.g., memory cell 104) is actually I_{OFFSET}+Δ₁. However, since the value of I_{OFFSET} may be large (e.g., a standard deviation of 500 nA), the I_{OFFSET} may saturate the INL correction circuits and consequently reduce accuracy of the calibration. It should be further noted that the residual current error of the first MSB, after calibration has been performed, is I_{OFFSET}+Δ₁, which is much larger than the remaining MSBs.

In an aspect, switch 166b may connect node 109 to node 164, switch 170 may connect node 143 to node 164, switch 134b may connect node 167 to node 141, and switch 136b may connect node 174 to the gate of transistor 146. With such a configuration, capacitor 150 is charged via closed switch 136b to store the sum of the current I_{OFFSET} and the residual current error with respect to the current source 158b.

The offset current I_{OFFSET} 156 of the current comparator circuit 140 may be reduced by optimizing the design of the current comparator circuit 140. Such optimization may include increasing the gain of the first stage of the current comparator circuit 140, reducing the first stage offset by increasing the size of the first stage, and/or avoiding any additional systematic offset by implementing appropriate layout techniques. However, such optimization may require either increased silicon area or complicated circuit design. Moreover, such optimization may be sensitive to process variations, which may not be accurately predicted using circuit models, especially in currently implemented processes, such as 20 nm CMOS.

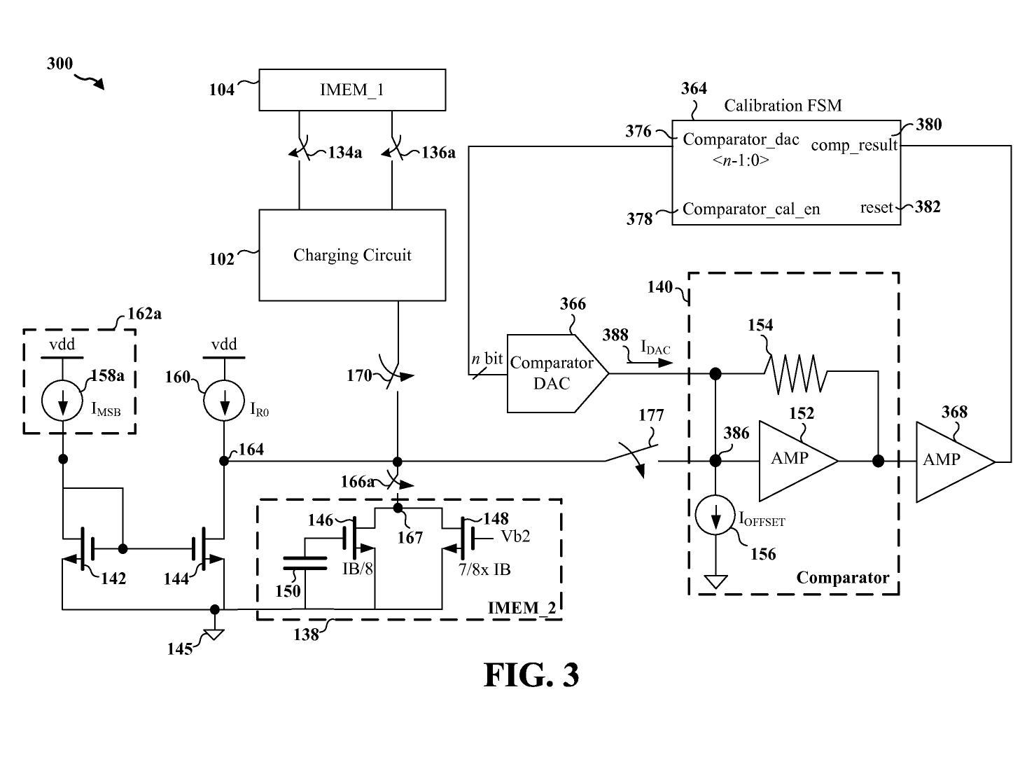

FIG. 3 is a diagram illustrating a DAC calibration circuit 300 in accordance with various aspects of the disclosure. In an aspect, the DAC calibration circuit 300 may be implemented in a DAC device. As shown in FIG. 3, DAC calibration circuit 300 includes charging circuit 102, memory cell (IMEM_1) 104, current comparator circuit 140, AMP 368, calibration finite state machine (FSM) 364, and comparator DAC 366. In FIG. 3, the details of the charging circuit 102, memory cell (IMEM_1) 104, and memory cell (IMEM_2) 138 have been omitted for ease of illustration. However, in an aspect, the charging circuit 102 and memory cell (IMEM_1) 104 in FIG. 3 may be configured similar to the charging circuit 102 and memory cell (IMEM_1) 104 as shown in FIG. 1.

In an aspect, memory cell (IMEM_2) 138 may be configured to store a residual current error (e.g., Δ₁) resulting from a previous calibration of a preceding DAC bit element (e.g., a DAC bit element preceding DAC bit element 162a). For example, the residual current error may be between a calibrated current source for the previous DAC bit element which provides current I_{MSBC} (e.g., I_{MSBC}=I_{MSB}+I_{CAL}) and a reference current source 160 that provides current I_{REF} (e.g., I_{REF}=I_{R0}+I_{REFDAC}) associated with the preceding DAC bit element. In an aspect, succeeding DAC bit elements may each be coupled to transistor 142 (e.g., one at a time) to effect residual current error sampling and storing operations for each succeeding DAC bit element.

In an aspect, prior to performing calibration of the current source 158a for the DAC bit element 162a, DAC calibration circuit 300 may calibrate the current comparator circuit 140 by cancelling the offset current I_{OFFSET} 156 at the input (e.g., node 386) of the current comparator circuit 140. In such aspect, DAC calibration circuit 300 may open switch 177 to electrically disconnect node 386 from node 164 in order to calibrate the current comparator circuit 140. For example, the DAC calibration circuit 300 may perform a digital feedback calibration to cancel or reduce the offset current I_{OFFSET} 156.

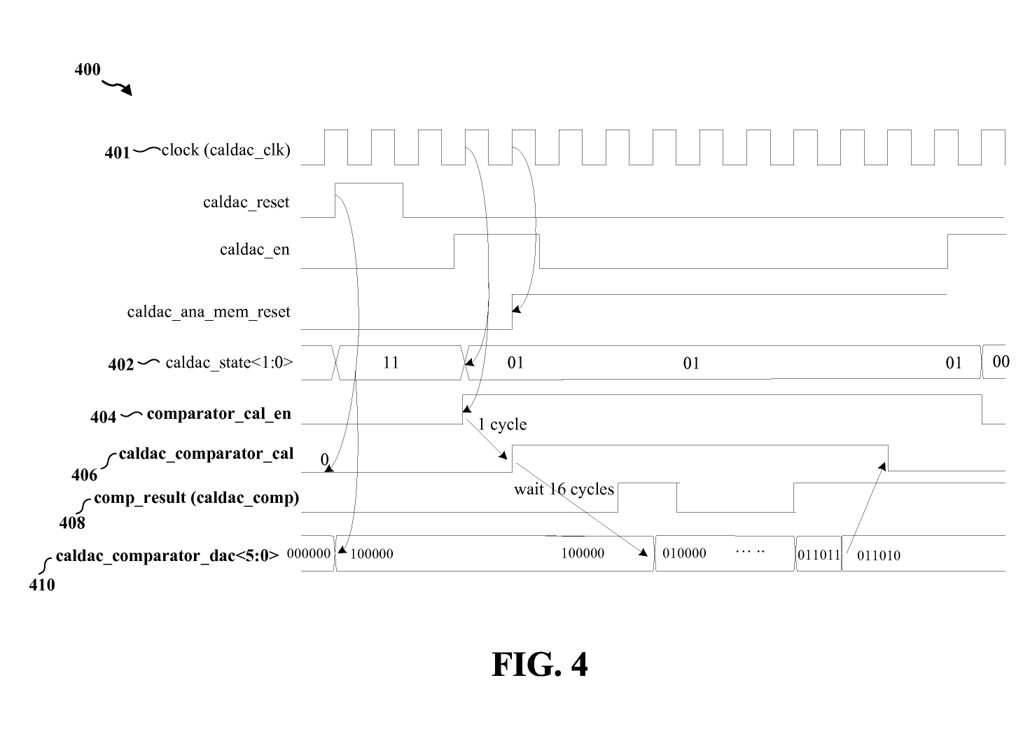

FIG. 4 is a diagram illustrating a timing sequence 400 for an FSM in accordance with various aspects of the disclosure. In an aspect, and with reference to the timing sequence 400 in FIG. 4, digital feedback calibration of the current comparator circuit 140 may be performed when the caldac_state 402 is in a 0:1 state. The calibration FSM 364 may receive an enable signal (comparator_cal_en) 404 at the Comparator_cal_en input 378, which will enable the calibration FSM 364 when the signal is a logic ‘1’ for example. With further reference to FIG. 4, after one cycle of clock 401, the calibration FSM 364 may receive a reset signal (caldac_comparator_cal) 406 at the reset input 382, which will reset the calibration FSM 364 when the reset signal 406 is a logic ‘1’ for example. After approximately 16 cycles of clock 401 (e.g., to allow the DAC calibration circuit 300 adequate time to stabilize), the calibration operation may be started. In an aspect, the calibration operation performed by the calibration FSM 364 is a successive-approximation algorithm based on the feedback 408 (e.g., the output from the amplifier 368 received at the comp_result input 380) from the current comparator circuit 140.

In an aspect, the comparator DAC 366 may be an n-bit DAC and the calibration

FSM 364 may be configured to output one or more n-bit words during the calibration. The comparator DAC 366 may be an unused CALDAC in a DAC device. It can be appreciated that the area of the calibration FSM 364 may be negligible in 20 nm CMOS technology. In one example, the comparator DAC 366 may be a 6-bit DAC and the calibration FSM 364 may be configured to output one or more 6-bit words (e.g., one or more 6 bit words of signal 410 in FIG. 4 output from Comparator_dac output 376 in FIG. 3), which may be received at the input of the comparator DAC 366. In an aspect, the calibration operation performed by the calibration FSM 364 determines an appropriate 6-bit word that enables the comparator DAC 366 to provide an output (e.g., current I_{DAC} 388) that cancels or reduces the I_{OFFSET} 156 at node 386. In an aspect, the output of the comparator DAC 366 cancels I_{OFFSET} 156 to the accuracy of the comparator DAC 366 least significant bit (LSB).

Therefore, after calibration of the current comparator circuit 140, the mismatch between the calibrated current source (I_{MSBC}) 158a and the reference current source (I_{REF}) 160 may be substantially reduced after calculation of the INL, except for the first DAC element (e.g., MSB1) which may be calibrated a second time in some aspects. Moreover, the cancellation of the I_{OFFSET} 156 may prevent saturation of the operational transconductance amplifier (OTA) inputs. After calibration of the current comparator circuit 140 is complete, the DAC calibration circuit 300 may close switch 177 to couple node 386 to node 164 to continue calibration of MSB for each successive DAC element. It should be noted that since I_{OFFSET} 156 is canceled or substantially reduced after calibration, each residual current error from a previous calibration may be sampled accurately for INL corrections and stored in a memory cell (e.g., memory cell 138).

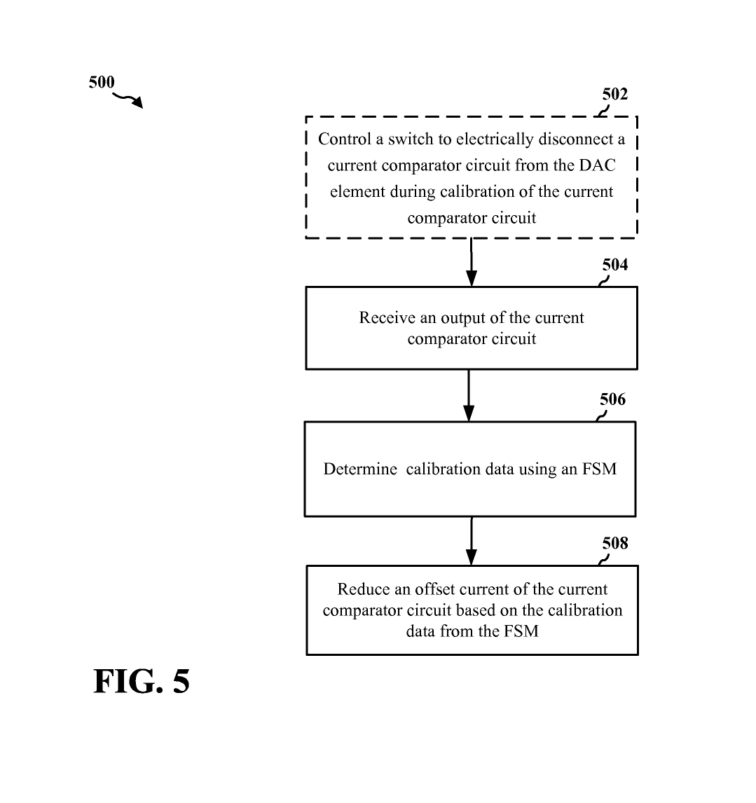

FIG. 5 is a flow chart 500 of a method of calibrating a current comparator circuit associated with a DAC element in accordance with various aspects of the disclosure. For example, the method may be performed by a DAC calibration circuit in a DAC device. In flow chart 500, steps represented with dotted lines represent optional steps. At step 502, the DAC calibration circuit controls a switch to electrically disconnect a current comparator circuit from a DAC element during calibration of the current comparator circuit. In an aspect, the current comparator circuit (e.g., current comparator circuit 140 in FIG. 3) is configured to calibrate a current source (e.g., current source 158a FIG. 3) of a DAC element (e.g., DAC element 162a in FIG. 3). At step 504, the DAC calibration circuit receives an output (e.g., feedback) of the current comparator circuit (e.g., current comparator circuit 140 in FIG. 3). At step 506, the DAC calibration circuit determines calibration data using an FSM (e.g., calibration FSM 364 in FIG. 3). In an aspect, the calibration data is determined based on the output of the current comparator circuit. Finally, at step 508, the DAC calibration circuit reduces an offset current (e.g., I_{OFFSET} 156 in FIG. 3) of the current comparator circuit based on the calibration data from the FSM. For example, the calibration data may be an n-bit word, where the DAC calibration circuit receives the n-bit word and provides a current that reduces the offset current of the current comparator module.

It is understood that the specific order or hierarchy of steps in the processes/flow charts disclosed is an illustration of exemplary approaches. Based upon design preferences, it is understood that the specific order or hierarchy of steps in the processes/flow charts may be rearranged. Further, some steps may be combined or omitted. The accompanying method claims present elements of the various steps in a sample order, and are not meant to be limited to the specific order or hierarchy presented.

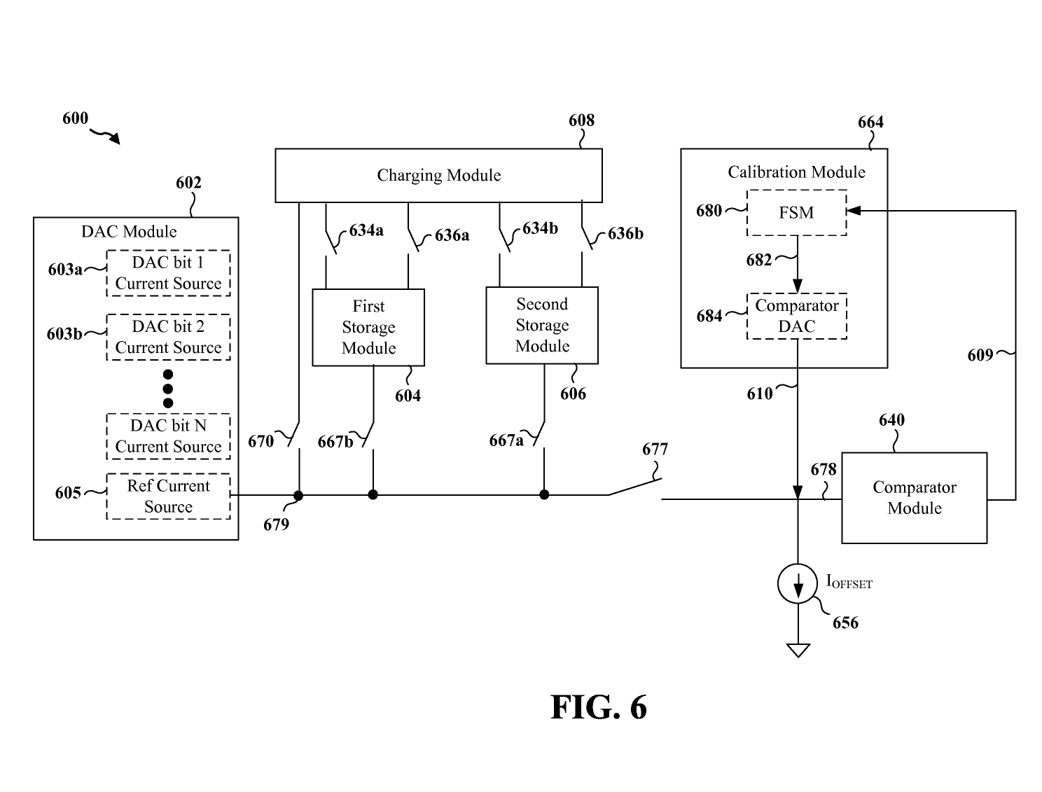

FIG. 6 is a block diagram of a DAC 600 in accordance with various aspects of the disclosure. As shown in FIG. 6, DAC 600 includes DAC module 602, first storage module 604, second storage module 606, charging module 608, current comparator module 640, and calibration module 664, which includes calibration FSM 680 and comparator DAC 684. In an aspect, switches 634a and 634b are closed to store a residual current error (e.g., Δ₁) associated with a current source 603a of a preceding DAC bit element (e.g., current source 603a of DAC bit 1) of the DAC module 602 and reference current 605 in first storage module 604. For example, the current source 603a corresponding to the preceding DAC bit element may be a current source that is calibrated with respect to the reference current source 605. In an aspect, after calibration, current source 603a may provide current I_{MSBC} (e.g., I_{MSBC}=I_{MSB}+I_{CAL}) and reference current source 605 may provide a reference current I_{REF} (e.g., I_{REF}=I_{R0}+I_{REFDAC}).

In an aspect, when calibrating the current source 603b of a successive DAC bit element (e.g., current source 603b of DAC bit 2) of the DAC module 602, DAC 600 may close switch 667b to couple the first storage module 604 to the node 679. As previously discussed, the first storage module 604 may be storing the sum of the current I_{OFFSET} and the residual current error (e.g., Δ₁) from the calibration of the current source 603a of the preceding DAC bit element. Accordingly, in such aspect, DAC 600 may close switch 667b to couple the first storage module 604 to node 679, open switch 670 to electrically disconnect the charging module 608 from the node 679, and close switch 677 to couple node 679 to the input 678 of the current comparator module 640. In such a configuration, the first storage module 604 sinks an amount of current equal to the sum of the current I_{OFFSET} and the residual current error (Δ₁) during calibration of the current source 603b of the successive DAC bit element to improve accuracy of the calibration.

In an aspect, DAC 600 may open switch 677, close switch 667b to couple the first storage module 604 to node 679, close switch 670 to couple an input of the charging module 608 to the node 679, and close switches 634b, 636b. In such a configuration, the second storage module 606 may store the sum of the current I_{OFFSET} and the residual current error with respect to the current source 603b via closed switch 636b for calibration of a subsequent DAC bit element (e.g., for calibration of current source 603b of DAC bit 2).

In an aspect, prior to performing calibration of the current source 603a for the preceding DAC bit element, calibration module 664 may calibrate the current comparator module 640 by reducing an offset current 656 (e.g., I_{OFFSET}) that may be present at the input 678 of the current comparator module 640. In such aspect, DAC 600 may open switch 677 to electrically disconnect the input 678 of the comparator module 640 from node 679 in order to calibrate the current comparator module 640. In an aspect, and as discussed infra, the DAC 600 may perform a digital feedback calibration to cancel or reduce the offset current I_{OFFSET} 656.

For example, and with reference to the timing sequence 400 in FIG. 4, digital feedback calibration of the current comparator module 640 may be performed when the caldac_state 402 is in a 0:1 state. The calibration FSM 680 may receive an enable signal (comparator_cal_en) 404, which will enable the calibration FSM 680 when the signal is a logic ‘1’ for example. With further reference to FIG. 4, after one cycle of clock 401, the calibration FSM 680 may receive a reset signal (caldac_comparator_cal) 406, which will reset the calibration FSM 680 when the reset signal 406 is a logic ‘1’ for example. After approximately 16 cycles of clock 401 (e.g., to allow the DAC 600 adequate time to stabilize), the calibration operation may be started. In an aspect, the calibration operation performed by the calibration FSM 680 is a successive-approximation algorithm based on the feedback 609 (e.g., the output from the comparator module 640) from the comparator module 640.

In an aspect, the comparator DAC 684 may be an n-bit DAC and the calibration FSM 680 may be configured to output 682 one or more n-bit words during the calibration. The comparator DAC 684 may be an unused CALDAC in a DAC device. In one example, the comparator DAC 684 may be a 6-bit DAC and the calibration FSM 680 may be configured to output 682 one or more 6-bit words (e.g., one or more 6 bit words of signal 410 in FIG. 4), which may be received at the input of the comparator DAC 684. In an aspect, the calibration operation performed by the calibration FSM 680 determines an appropriate 6-bit word that enables the comparator DAC 684 to provide an output 610 (e.g., current I_{DAC}) that cancels or reduces the I_{OFFSET} 656 at input 678 of the comparator module 640. In an aspect, the output of the comparator DAC 684 cancels I_{OFFSET} 656 to the accuracy of the comparator DAC 684 least significant bit (LSB).

In an aspect, an apparatus for calibrating a DAC element includes means for controlling a switch to electrically disconnect a current comparator module from the DAC element during calibration of the current comparator module. For example, the means for controlling the switch to electrically disconnect the current comparator module from the DAC element may be the switch 177 of the DAC calibration circuit 300 in FIG. 3. As another example, the means for controlling the switch to electrically disconnect the current comparator module from the DAC element may be the switch 677 of the DAC 600 in FIG. 6. The apparatus further includes means for receiving an output of a current comparator module. For example, the means for receiving the output of the current comparator module may be the FSM 364 (e.g., the comp_result input 380) in FIG. 3. As another example, the means for receiving the output of the current comparator module may be the FSM 680 in FIG. 6. The apparatus further includes means for determining calibration data using an FSM based on the output of the current comparator module. For example, the means for determining calibration data may be the FSM 364 in FIG. 3. As another example, the means for determining calibration data may be the FSM 680 in FIG. 6. The apparatus further includes means for reducing an offset current at an input of the current comparator module based on the calibration data from the FSM. For example, the means for reducing an offset current may be the comparator DAC 366 in FIG. 3. As another example, the means for reducing the offset current may be the comparator DAC 684 in FIG. 6. In an aspect, the calibration data is an n-bit word, where the means for reducing the offset current is configured to receive the n-bit word and provide a current that reduces the offset current of the current comparator module. For example, the current that reduces the offset current may be the current I_{DAC} 388 in FIG. 3. As another example, the current that reduces the offset current may be the output 610 of the comparator DAC 684 in FIG. 6.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EPSOM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASICS. The ASICS may reside in a user terminal. In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A nontransitory storage media may be any available media that can be accessed by a computer. By way of example, and not limitation, such nontransitory computer-readable storage media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. In addition, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Combinations of the above should also be included within the scope of computer-readable media.

The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. An apparatus for calibrating a digital-to-analog converter (DAC) element, comprising:
a current comparator module coupled to the DAC element, the current comparator module configured to calibrate a current source corresponding to the DAC element; and
a calibration module coupled to the current comparator module and configured to reduce an offset current of the current comparator module, the calibration module comprising:
a finite state machine (FSM) configured to receive feedback from the current comparator module and to generate calibration data based on the feedback, and
a comparator DAC configured to reduce an offset current of the current comparator module based on the calibration data from the FSM.

2. The apparatus of claim 1, wherein the calibration module and the current comparator module are coupled to the DAC element via a switch, the switch being configured to electrically disconnect the calibration module and the current comparator module from the DAC element during calibration of the current comparator module.

3. The apparatus of claim 1, wherein the current comparator module is configured to calibrate a current source of the DAC element.

4. The apparatus of claim 1, wherein the calibration data is an n-bit word, the comparator DAC further configured to receive the n-bit word and output a current that reduces the offset current of the current comparator module.

5. The apparatus of claim 1, wherein an amount of current output by the comparator DAC is controlled by the calibration data.

6. The apparatus of claim 1, wherein the reduced offset current of the current comparator module is configured to prevent saturation at an input of the current comparator module during residual current error sampling for the DAC element.

7. The apparatus of claim 1, wherein the current comparator module comprises a transimpedance amplifier.

8. A method of calibrating a digital-to-analog converter (DAC) element:
receiving an output of a current comparator module;
determining calibration data using a finite state machine (FSM) based on the output of the current comparator module; and
reducing an offset current at an input of the current comparator module based on the calibration data from the FSM.

9. The method of claim 8, further comprising controlling a switch to electrically disconnect the current comparator module from the DAC element during calibration of the current comparator module.

10. The method of claim 8, wherein the current comparator module is configured to calibrate a current source of the DAC element.

11. The method of claim 8, wherein the calibration data is an n-bit word, the reducing the offset current comprising receiving the n-bit word and providing a current that reduces the offset current of the current comparator module.

12. The method of claim 8, wherein reducing the offset current comprises providing an amount of current that reduces the offset current of the current comparator module, the amount of current controlled by the calibration data.

13. The method of claim 8, wherein the reduced offset current of the current comparator module is configured to prevent saturation at the input of the current comparator module during residual current error sampling for the DAC element.

14. The method of claim 8, wherein the current comparator module comprises a transimpedance amplifier.

15. An apparatus for calibrating a digital-to-analog converter (DAC) element:
means for receiving an output of a current comparator module;
means for determining calibration data using a finite state machine (FSM) based on the output of the current comparator module; and
means for reducing an offset current at an input of the current comparator module based on the calibration data from the FSM.

16. The apparatus of claim 15, further comprising means for controlling a switch to electrically disconnect the current comparator module from the DAC element during calibration of the current comparator module.

17. The apparatus of claim 15, wherein the current comparator module is configured to calibrate a current source of the DAC element.

18. The apparatus of claim 15, wherein the calibration data is an n-bit word, the means for reducing the offset current configured to receive the n-bit word and provide a current that reduces the offset current of the current comparator module.

19. The apparatus of claim 15, wherein the means for reducing the offset current is configured to provide an amount of current that reduces the offset current of the current comparator module, the amount of current controlled by the calibration data.

20. The apparatus of claim 15, wherein the reduced offset current of the current comparator module prevents saturation at the input of the current comparator module during residual current error sampling for the DAC element.
